(19) United States
(12) Patent Application Publication
(10) Pub. No.: US 2024/0200765 A1
(43) Pub. Date: Jun. 20, 2024

(54) A VAPOR CHAMBER

(71) Applicant: SIGNIFY HOLDING B.V., EINDHOVEN (NL)

(72) Inventors: TIES VAN BOMMEL, HORST (NL); JIANG HONG YU, BEST (NL); GENEVIEVE THERESE MARTIN, UDENHOUT (NL); DERK TIEKINK, MIERLO (NL)

(21) Appl. No.: 18/556,423

(22) PCT Filed: Apr. 15, 2022
(86) PCT No.: PCT/EP2022/060163

§ 371 Date: Oct. 20, 2023

(30) Foreign Application Priority Data
Apr. 23, 2021 (EP) 21170040.6

(51) Int. Cl. F21V 29/51; F21Y 113/00; F21Y 115/10

(52) U.S. Cl. CPC F21V 29/51; F21Y 2113/00; F21Y 2115/10

(57) ABSTRACT

This invention relates to a vapor chamber (100) comprising a first thermally conductive plate (110) and a second thermally conductive plate (120) separated from each other by a plurality of bridging elements (140) to form a cavity (130) having a first height, H1 (001). The vapor chamber (100) comprises a bending section (151) and a non-bending section (152). The bending section (151) is configured to provide a bend having a first volume fraction (V1) of bridging elements (140), and the non-bending section (152) having a second volume fraction (V2) of bridging elements (140). A ratio of the first volume fraction (V1) and the second volume fraction (V2) is less than 0.7.

### FIELD OF THE INVENTION

The invention relates to a vapor chamber. The invention further relates to a method for providing a bent vapor chamber. The invention further relates to a device comprising the bent vapor chamber.

### BACKGROUND OF THE INVENTION

Vapor chambers are known in the art. For instance, US2010226138A1 describes a road lamp holder structure that includes a lamp guard, an LED unit installed at the bottom of the lamp guard, and a heat dissipating device installed in the lamp guard and having a base, a vapor chamber, and two heat-dissipating elements attached to the LED unit. The vapor chamber includes a heated section attached to the base, two heat-transmitting sections bent and extended upward from both sides of the heated section respectively, a condensing section bent and extended laterally from each of the two heat-transmitting sections, two heat-dissipating elements having a heated base, and heat-dissipating fins disposed on the heated base. The two heated bases are attached to the external sides of the two heat-transmitting sections of the vapor chamber respectively, and the two condensing sections of the vapor chamber are attached to the internal periphery of the top of the lamp guard.

In US2020326134 a flexible vapor chamber for an electronic device includes an upper cover, a lower cover, an accommodation space, a capillary structure, plural support structures and a working fluid. The accommodation space is arranged between the upper cover and the lower cover. The capillary structure is disposed on the lower cover and accommodated within the accommodation space. The plural support structures are disposed on the upper cover and accommodated within the accommodation space. The plural support structures are contacted with the capillary structure.

### SUMMARY OF THE INVENTION

The compactness of electronic components may be becoming increasingly important, for example in the context of LED lighting. With the requirements for miniaturization, new technologies and solutions may be desired for the next generations of electronic components.

The prior art may describe electronic components, such as a driver, in a housing, wherein otherwise empty space in the housing is filled up with thermal interface materials. However, thermal interface materials, such as polymer-based composites and graphite type thermal interface materials, may typically have a maximum thermal conductivity of less than 400 W/mK.

It appears that vapor chambers with thermal conductivities in the range of 15000-27000 W/mK may be possible. However, the vapor chambers may not easily be suitable for device miniaturization. In particular, the vapor chambers may be restricted to either a planar configuration, at which maximum heat exchange may be achieved or to a bent configuration with a bending radius such as, for example, 10 mm, which may block device miniaturization. In particular, prior art vapor chambers may rapture when bent at a smaller bending radius suitable for device miniaturization.

Therefore, it is desirable to provide a vapor chamber that can be bent with a small bending radius (e.g. less than 10 mm) with ease. Besides miniaturization, a bent vapor chamber with a small bending radius may be suitable for configuring in a meandering shape for achieving a high surface area for heat dissipation. Which may subsequently improve the thermal load or capacity of a vapor chamber. A bent vapor chamber with a small bending radius may also be suitable for configuring in other advanced shapes for achieving a high surface area for heat dissipation.

Hence, it is an aspect of the present invention to provide an alternative vapor chamber, which preferably further at least partly alleviates one or more of the above-described draw backs or attains one or more additional advantages. The present invention may have as an object to overcome or ameliorate at least one of the disadvantages of the prior art or to provide a useful alternative.

According to a first aspect of the invention, a vapor chamber is provided. The vapor chamber comprising a first thermally conductive plate and a second thermally conductive plate separated from each other by a plurality of bridging elements to form a chamber having a first height, H1. The vapor chamber is having a length L along a longitudinal axis and a width W defined perpendicular to the longitudinal axis. The length L and the width W are oriented in parallel with the conductive plates.

The vapor chamber comprises a bending section and a non-bending section. The bending section is configured to provide a bend around an axis in a direction parallel with the width W, said vapor chamber is further having a first volume fraction (V₁) of bridging elements, and the non-bending section having a second volume fraction (V₂) of bridging elements. A ratio of the first volume fraction (V₁) and the second volume fraction (V₂) is less than 0.7.

The vapor chamber of the invention may provide the benefit that vapor chambers with a small bending radius may be obtained. In particular, the bending section may facilitate easier bending of the vapor chamber, especially bending at a relatively low bending radius. In particular, the decreased local density of bridging elements may at least partially collapse during bending.

Further, it is clear that the bending is in a direction around a bending axis that is in parallel with the width W, meaning that the conductive plates will be curved along the longitudinal axis.

In other words, according to a first aspect of the invention, a vapor chamber element. The vapor chamber element comprises a first plate and a second plate with a chamber in between, wherein the chamber has a first height, wherein the vapor chamber element further comprises bridging elements bridging at least part of the first height H1, wherein the vapor chamber element comprises a plurality of sections configured along a longitudinal axis, wherein the plurality of sections comprises (i) a bending section having a first volume fraction (V1) of bridging elements, and (ii) a basic section having a second volume fraction (V2) of bridging elements, wherein V1/V2<0.7. The terms “vapor chamber element” and “vapor chamber” may be used interchangeably.

In the context of the present invention, the term ‘bending section’ may be considered as a section where one may bend the vapor chamber. In that respect, the term ‘non-bending section’ or ‘basic section’ may be considered as a section where one may not bend the vapor chamber. A bending section may be adjacent to a non-bending section or basic section. Also, a bending section may also have two neighboring non-bending or basic sections.

A bending section may have a bending subsection, and/or one or two support subsections. A bending subsection is where the bending of the vapor chamber takes place. The bending subsection may have adjacent one or more support subsections. The support subsections may have a greater volume fraction of bridging elements than the volume fraction of bridging elements of the bending subsection. However, the support subsections may have a smaller volume fraction of bridging elements than the second volume fraction (V2) of bridging elements of the non-bending section. The first volume fraction (V1) of bridging elements may be determined for the bending section considering the bending subsection, and/or one or two support subsections if present with the bending subsection.

Vapor chamber (also: “VC”) is known in the art and may be based on essentially the same principle as heat pipe (which is also known in the art). Both systems are known as “two-phase devices”. Both two-phase devices may include a wick structure (sintered powder, mesh screens, and/or grooves) applied to the inner surface(s) or wall(s) of an enclosure (tube or planar shape). Liquid, such as water (e.g. for a copper device) or acetone (e.g. for an aluminum device), may be added to the VC, and the VC may be vacuum sealed. The wick may distribute the liquid throughout the device. However, when heat is applied to one area of the two-phase device, the liquid turns to vapor and moves to an area of lower pressure where it cools and returns to liquid form whereupon it moves back to the heat source by virtue of capillary action (through the wick). A common wick structure may be a sintered wick type because it offers a high degree of versatility in terms of power handling capacity and ability to work against gravity. Mesh screen wicks may allow the heat pipe or vapor chamber to be thinner relative to a sintered wick. Also, a grooved wick may be applied. The grooves may act as an internal fin structure aiding in the evaporation and condensation. A difference between the heat pipe and the vapor chamber may be that the heat pipe may have an essentially rod-shaped shape, whereas the vapor chamber may in general include two essentially planar thermally conductive plates at a relatively short distance (such as up to 5 mm). Further, the hot spot may be relatively freely chosen for the vapor chamber, whereas for a heat pipe there is a hot and cold side.

The vapor chamber may comprise a first thermally conductive plate and a second thermally conductive plate, especially with a chamber in between. The first thermally conductive plate and the second thermally conductive plate may especially be arranged in parallel.

Materials of the first thermally conductive plate and the second thermally conductive plate may be selected from the group consisting of copper, stainless steel, aluminum, and titanium. Hence, the first thermally conductive plate may comprise a material selected from the group comprising copper, stainless steel, aluminum, and titanium. In further embodiments, the second thermally conductive plate may comprise a material selected from the group comprising copper, stainless steel, aluminum, and titanium. Especially, both plates may consist of the same material. Also, material combinations may be applied, such as alloys.

In particular, over a substantial part of the first thermally conductive plate and a substantial part of the second thermally conductive plate, the thermally conductive plates may be configured parallel. For instance, over at least 50%, such as at least 80%, like at least 90% of an area of the first plate, and over at least 50%, such as at least 80%, like at least 90% of an area of the second thermally conductive plate, the thermally conductive plates may be configured parallel. Hence, over a substantial part of the first thermally conductive plate and a substantial part of the second thermally conductive plate, the “first height, H1” is the distance between the thermally conductive plates, which may not essentially vary. The first thermally conductive plate and the second thermally conductive plate may especially approximate a (same) rectangular shape, such as a rounded rectangular shape.

The first thermally conductive plate and the second thermally conductive plate may be shaped from a single thermally conductive plate. In particular, a single thermally conductive plate may have been bent to provide the first thermally conductive plate and the second thermally conductive plate, especially separated at a distance. This distance may define “a first height” of a chamber in between.

The first thermally conductive plate and the second thermally conductive plate may be two separate thermally conductive plates. In particular, the first thermally conductive plate and the second thermally conductive plate may be welded together at their edges to provide a closed chamber.

The vapor chamber may further comprise a plurality of side thermally conductive plates, bridging the first thermally conductive plate (also: “top plate”) and the second thermally conductive plate (also: “bottom plate”), wherein the chamber is arranged in between the first thermally conductive plate, the second thermally conductive plate and the plurality of side thermally conductive plates. The vapor chamber, especially the chamber defined by the thermally conductive plates, may have a shape approximating a cuboid, especially a bar, such as a cuboid with rounded (internal) corners.

The chamber may have “a first height”, especially an average distance between the first thermally conductive plate and the second thermally conductive plate. In particular, as the first thermally conductive plate and the second thermally conductive plate may be arranged essentially in parallel, the first height may be essentially constant throughout the chamber.

The first height may be selected from the range of 50 μm-5 mm. The first height may be at a maximum of 1 mm. The first height may even be equal to or smaller than 0.4 mm, e.g. in the range of 100-400 μm, like 200-400 μm, such as at least 250 μm.

The vapor chamber further comprises bridging elements bridging at least part of the first height. The bridging elements may provide support to the vapor chamber, especially to the chamber. In particular, the bridging elements may connect the first thermally conductive plate and the second thermally conductive plate, thereby improving the stability (or “rigidity”) of the vapor chamber. The bridging elements may especially comprise (supporting) columns. The columns may be massive. Alternatively, the columns may be hollow.

The vapor chamber may comprise a plurality of sections comprising a bending section and a non-bending section configured along a longitudinal axis. In particular, the chamber may be sectioned into a plurality of sections along the longitudinal axis. The bending section and the non-bending section may be adjacent to each other. The bending section and the non-bending section may especially be non-overlapping. The bending section and the non-bending section may especially be (essentially) defined by a plurality of planes perpendicular to the longitudinal axis, wherein each section comprises the part of the chamber in between the planes, i.e., in general, the bending section and the non-bending section are arranged along a single dimension. Hence, the chamber may be defined by at least two sections, even more especially at least two sections (of which at least one is a bending section: see also below).

Each of the bending section and the non-bending section may have a volume. The total volume of the sections is the volume of the vapor chamber. Note that the sections may enclose a wick structure, bridging elements, and may host at least part of the coolant (liquid and/or gas): see also below.

The bending section may especially be configured for bending, i.e., the vapor chamber may be configured to be bent at the bending section. Hence, at least one of the sections is a bending section.

A bending section is part of the vapor chamber wherein the vapor chamber element can be bent or is bent. And the non-bending section is a relatively straight section that can be used for heat transfer, for example, cooling. The non-bending section of the vapor chamber may come in thermal contact with a device or an object that needs heating or cooling. So, the first thermally conductive plate or the second thermally conductive may be used for creating the aforementioned thermal contact with the device or the object.

In particular, the bending section may have a first volume fraction V₁ of bridging elements. The phrase “volume fraction of bridging elements” may herein especially refer to a fraction of the section, which is a part of the chamber, that comprises bridging elements. In particular, each section may be divided into bridging elements, a wick structure, and open space, wherein the open space may, during operation, especially comprise liquid and/or gas.

In general, with a lower volume fraction of the bridging elements, the corresponding section may become weaker and therefore may allow an easier bending with high bending angles and a small bending radius. This may be particularly challenging for the prior art vapor chambers that have a higher or equal volume fraction of the bridging elements at the bending section compared to a non-bending section, resulting in a rapture of the device when bent at a smaller bending radius. Additionally, a smaller volume fraction comprising bridging elements may also result in an improved movement of gas and/or liquid through a bending section which may have a partial narrowing of the chamber due to the bending or folding at the bending section or bending subsection with high bending angles and a small bending radius. This may have an advantageous effect on the heat exchange, especially cooling, provided by the vapor chamber. For the prior art vapor chambers, this aforementioned effect may not achievable since the narrowing of the chamber is accompanied by a higher or equal volume fraction of the bridging elements at the bending section compared to a non-bending section. However, the movement of gas and/or liquid through a bending section which may have a partial narrowing may be also dependent on the extent of narrowing of the chamber. Hence, there may be a trade-off between the stability and the cooling capacity of the vapor chamber.

Also, the chamber at the bending section or bending subsection may completely close due to the bending to the bending or folding at the bending section or bending subsection with high bending angles and a small bending radius. This may prevent fluid flow. However, one should understand, while the first thermally conductive plate or the second thermally conductive may be in thermal contact with the device or the object that needs heating or cooling, the counterpart thermally conductive plate would be in the thermal contact through the fluid in the chamber and wick structures and may still allow sufficient heat transfer.

The plurality of sections may further comprise a non-bending section, especially at least two non-bending sections having a bending section in between, each of the non-bending sections having a second volume fraction V₂ of bridging elements.

A ratio of the first volume fraction V₁ and the second volume fraction V₂ is less than 0.3.

The ratio of the first volume fraction V₁ and the second volume fraction V₂ may be greater than or equal to 0, but less than 0.3. Therefore, the first volume fraction V₁ may represent a value greater than or equal to 0 and the second volume fraction V₂ may represent a value greater than 0.

The ratio of the first volume fraction V₁ and the second volume fraction V₂ may be selected from a range between 0 and 0.3.

Hence, the bending section may have a substantially lower volume fraction of bridging elements than the non-bending section.

The non-bending section of the vapor chamber may ‘N’ number of bridging elements. Preferably ‘N’ is at least 25, more preferably ‘N’ is at least 40, most preferably ‘N’ is at least 50. The number of bridging elements ‘Nb’ in the bending section is smaller than the ‘N’ number of bridging elements in the non-bending section of the vapor chamber. At the bending section or the bend subsection, the number of bridging elements ‘Nb’ can be zero.

The bending section may especially be configured between two non-bending sections.

The vapor chamber may have a length, L defined in a longitudinal axis and a width, W defined perpendicular to the longitudinal axis. And a ratio of the length, L, and the width, W may be selected from a range between 0.2 and 5.

The vapor chamber may comprise a first chamber end and a second chamber end defining the length, L. In general, the chamber will have a length, L, and a width (an average width), W that are substantially larger than the first height, H1 of the chamber, or the thickness, de of the vapor chamber. Further, in general, the chamber will have a cross-section that is essentially rectangular. The vapor chamber, especially the chamber, may have an axis of elongation, herein referred to as a longitudinal axis. The axis of elongation may especially be an axis along which the length of the vapor chamber may be defined. Hence, the vapor chamber may have an elongated shape having a longitudinal axis.

If the width, W varies along the longitudinal axis, then the terms ‘width’ may refer to average width.

Further, in general, thickness, de may be much smaller than the length, L and/or width, W of the chamber. Hence, the length, L, and the first height (H1) may have a ratio selected from the range of L/H1≥10, such as ≥20, like selected from the range of 10-10,000. Alternatively or additionally, the width, W, and the first height, H1 may have a ratio selected from the range of W/H1≥10, such as ≥20, like selected from the range of 10-10,000.

The length, L may e.g. be selected from the range of 1 to 50 cm, such as 2 to 40 cm, like selected from the range of 2 to 20 cm, such as in the range of 4 to 15 cm, e.g. 5 to 12 cm. Likewise, this may apply to the width, W. In general, the width, W may be smaller than the length, L.

The chamber volume may be at least about 1 mm³, even more especially at least about 1 cm³. The chamber volume may be at a maximum of about 25 cm³, even more especially at a maximum of about 10 cm³.

The first thermally conductive plate and the second thermally conductive plate may respectively have a first thickness, d₁, and a second thickness, d₂ independently selected from the range of 50-5000 μm, such as 100-2000 μm, like especially 300-2000 μm. The phrase “independently selected” and similar phrases may refer to examples wherein for the relevant elements the same value of the parameter is chosen, i.e. in these examples both thermally conductive plates may have the same thickness, but may also refer to examples wherein for the relevant elements different values of the parameter is chosen, i.e. in these examples both thermally conductive plates may have a thickness selected from the indicated range, but they may have different thicknesses. Further, the first and second thickness(es) may also vary over the first thermally conductive plate and/or the second thermally conductive plate.

The thicknesses of the first thermally conductive plate and the second thermally conductive plate and the space between the thermally conductive plates may essentially define the thickness of the vapor chamber. Hence, the vapor chamber may have a thickness de, wherein dₑ=d₁+d₂+H1.

The first volume fraction V₁ may be selected from the range of 0 to 0.2, especially from the range of 0 to 0.1, such as from the range of 0 to 0.01.

The width, W may vary along the longitudinal axis from a first width value, W₁ to a second width value, W₂. The second width value, W₂ may be selected from a range between 0.1 times of the first width value, W₁ to 5 times of the first width value, W₁.

The width, W may vary along the longitudinal axis from a first width value, W₁ to a second width value, W₂ and a relation between the width, W along the longitudinal axis may be defined by a linear function or a step function.

Varying width, W of a vapor chamber along the longitudinal axis may help realize different designs or patterns of the vapor chamber. Such patterns may have advantages for making a bent vapor chamber with meandering shapes.

The vapor chamber may comprise an ‘n’ number of the bending sections, and an ‘(n−1)’ or ‘(n+1)’ number of the non-bending sections. The ‘n’ may be selected from a range between 2 to 20, and the non-bending sections may be arranged between two of the neighboring bending sections.

In particular, when the vapor chamber is to be bent at a single location, the vapor chamber may be provided such that a bending section is arranged at the location where the vapor chamber is to be bent, and wherein the remainder of the vapor chamber, especially the chamber, may comprise non-bending sections, i.e., especially two non-bending sections.

The vapor chamber may be bent at multiple locations, the vapor chamber may comprise a plurality of ‘n’ bending sections arranged at the multiple locations where the vapor chamber is to be bent, and the remainder of the vapor chamber, especially the chamber, may comprise non-bending sections, i.e., especially at least ‘n−1’ basic sections, such as at least basic sections, or especially ‘n+1’ basic sections.

The vapor chamber may comprise ‘n’ bending sections, especially wherein ‘n’ may be selected from the range of 2 to 20, such as from the range of 2 to 15, more preferably from the range of 3 to 10.

The vapor chamber may have a thickness, dₑ. The bending section may be configured to provide a bend having a bending angle, θ, a bending radius, r_{b}, and a bending length, L_{b} along the longitudinal axis, and wherein the bending length, L_{b} may be greater than or equal to π*(r_{b}+dₑ)/(360/θ).

In embodiments, the bending section may have a bending length, L_{b} along the longitudinal axis. The bending length, L_{b} may especially be selected to be sufficient to provide the bend. The bending length, L_{b} may especially be selected on the basis of the bend that is desired. In particular, the larger the angle of the desired bend, the larger the bending length, L_{b} may be to facilitate acquiring the desired bend. Similarly, the larger the thickness of the vapor chamber element, the larger the required bending length, L_{b} may need to be to achieve a specific angle. Hence, in embodiments. L_{b}≥π*(r_{b}+dₑ)/(360/θ).

The bending section may be configured to provide adjacent support subsections adjacent to the bend. Hence, the bending section may comprise a bending subsection configured to provide the bend, and two support subsections arranged at either side of the bending subsection. In particular, each support subsection may have a support length, Lₛₛ selected from the range of 3*dₑ to 20*dₑ, such as from the range of 5*dₑ to 10*dₑ. Hence, the bending length, L_{b} may especially be at least π*(r_{b}+dₑ)/(360/θ)+2*3*dₑ, such as π*(r_{b}+dₑ)/(360/θ)+2*5*dₑ. Alternatively, the bending length, L_{b} may especially be selected from the range of π*(r_{b}+dₑ)/(360/θ)+2*3*dₑ to π*(r_{b}+dₑ)/(360/θ)+2*20*dₑ, or especially from the range of π*(r_{b}+dₑ)/(360/θ)+2*5*dₑ to π*(r_{b}+dₑ)/(360/θ)+2*10*dₑ.

Hence, the vapor chamber may have an element thickness dₑ, wherein the bending section is configured to provide a bend having. 0, and a bending radius, no, wherein the bending section may have a bending length, L_{b}, and wherein the bending length, Lo may be selected from the range of π*(r_{b}+dₑ)/(360/θ)+2*5*dₑ to π*(r_{b}+dₑ)/(360/θ)+2*10*dₑ. It will be clear to the person skilled in the art that the bending length, L_{b} (along the longitudinal axis) may especially be defined prior to the bend being made. In particular, the bending radius, no may be the inner radius of the bend of the inner thermally conductive plate in the bend, wherein the outer radius is related to the bend of the outer thermally conductive plate in the bend. Therefore, the inner radius may be smaller than the outer radius.

The bending radius, r_{b} may be less than or equal to 3 mm.

The vapor chamber may be configured for bending at the bending section. In particular, the bending section may be configured such that the bending section can be bent at a bending radius, r_{b}, especially an inner bending radius rᵢ, or an outer bending radius rₒ, wherein the bending radius r_{b}≤3 mm, such as ≤2 mm, especially ≤1.5 mm, such as ≤1 mm.

The bending angle, θ may be selected from a range between 45 degrees and 135 degrees.

The term “bending radius” may herein especially refer to the radius of the circle best approximating a bend. The bend may especially correspond to at least 10% of the circumference of the circle, such as to at least 20%, especially at least 45%. The bend may correspond to about 25% of the circumference of a circle, i.e., the vapor chamber may be bent at a bending angle, θ of about 90°. The bend may correspond to about 50% of the circumference of a circle, i.e., the vapor chamber may be bent at a bending angle, θ of about 180°. Especially, the bent may be over e.g. 45° or 90° or 180°, though other angles may also be possible. Upon bending of a plate-shaped element, the plate may provide an inner bend and an outer bend, wherein the outer band may have a (slightly) bigger bending radius, especially dependent on the thickness of the vapor chamber. Hence, the bending radius may especially refer to an inner bending radius, rᵢ. The term “bending radius” may especially refer to an outer bending radius, ro.

The term “bending radius” may also refer to an average bending radius determined from the inner bending radius, rᵢ, and the outer bending radius, rₒ, which may be considered as a virtual bending line between the inner thermally conductive plate and the outer thermally conductive plate. If the inner thermally conductive plate is the first thermally conductive plate, then the outer thermally conductive plate is the second thermally conductive plate. Similarly, if the inner thermally conductive plate is the second thermally conductive plate, then the outer thermally conductive plate is the first thermally conductive plate.

The chamber may comprise a wick structure. The wick structure may comprise a first wick structure attached to an inner surface of the first thermally conductive plate facing the chamber and a second wick structure attached to an inner surface of the second thermally conductive plate facing the chamber.

The chamber, especially the wick structure, may comprise a first wick structure associated with the first thermally conductive plate, specially arranged in physical contact with the first thermally conductive plate, and/or a second wick structure associated with the second plate, specially arranged in physical contact with the second plate.

The wick structure may be arranged in the bending section and/or the non-bending section, especially in the bending section, or especially in the non-bending section.

The plurality of bridging elements may comprise columns.

The bridging elements may bridge at least 50% of the first height, H1, such as at least 70% of the first height, especially at least 90%, including 100%. In particular, the bridging elements may connect the first thermally conductive plate and the second thermally conductive plate, i.e., the first thermally conductive plate and the second thermally conductive plate may (at least) be connected via the bridging elements. Hence, the bridging elements may have heights of at least 0.5*H1, more especially at least 0.7*H1, yet even more especially at least about 0.9*H1.

The bridging elements may be metal bridging elements. For instance, the bridging elements may be copper elements. Alternatively or additionally, the bridging elements may be ceramic bridging elements. Alternatively or additionally, the bridging elements may be plastic bridging elements. It will be clear to the person skilled in the art that the plastic bridging elements would comprise a plastic that has a suitable glass transition temperature (for use in a vapor chamber) and that would (essentially) not react with the liquid in the vapor chamber.

The bridging elements may comprise (metal) columns. In particular, the columns may have a shape selected from the group consisting of a sphere, a plate, and a cylinder.

The columns may in embodiments have a circular cross-section. The columns may have a square cross-section. The columns may have an ‘n’-gonal cross-section, wherein ‘n’ is at least 5, like hexagonal (n=6), or octagonal (n=8).

Especially, the bridging elements may have a shape approximating a sphere. The spherical shape may be particularly convenient for the construction of the vapor chamber while providing good stability.

The bridging elements may have a spherical shape, the diameter of the bridging elements may especially be selected from the range of 0.8*H1 to H1. In particular, the diameter of the spherical bridging elements may be the first height.

The bridging elements may have a cylindrical shape, the height of the cylinder may especially be arranged parallel to the first height, H1. Further, the diameter of the cylinder may especially be selected from the range of 0.8*H1 to H1. In particular, the diameter of the cylindrical bridging elements may be equal to the first height, H1.

Hence, the bridging elements may have an equivalent circular diameter selected from the range of about 0.8*H1 to H1. The equivalent circular diameter (or ECD) of an (irregularly shaped) two-dimensional shape is the diameter of a circle of equivalent area. For instance, the equivalent circular diameter of a square with the side, ‘a’ is 2*a*SQRT(1/π). For a circle, the diameter is the same as the equivalent circular diameter. If a circle in an XY-plane with a diameter ‘D’ be distorted to any other shape (in the xy-plane), without changing the area size, then the equivalent circular diameter of that shape would be ‘D’. However, the bridging elements may also have cross-sections having larger equivalent circular diameters, such as selected from the range of about 0.8*H₁ to H₁. Especially, the bridging elements may have cross-sections having equivalent circular diameters equal to or smaller than about 0.2*W, even more especially at maximum 0.05*W.

The bridging elements may have a plate shape, the plate may especially be placed in direction of the (intended) flow. Hence, the flow direction is chosen in the direction of the length of the plate(s).

The bridging elements may have provided by a corrugated element. Hence, the vapor chamber may enclose an element, such as a corrugated element, which may consist of the bridging elements or which may consist of bridging elements and connector elements between the bridging elements. The bridging elements may be connected elements that may form a corrugated structure.

The wick structure may comprise (at least part of) the bridging elements, i.e., the bridging elements may at least partly be comprised by the wick structure.

Especially, the bridging elements may be extended from the wick structure. For instance, the wick structure(s) may have a height or a thickness that is maximum of 0.4*H1, such as at a maximum of 0.25*H1.

The columns may, with regards to the longitudinal axis, have one or two neighboring columns, i.e., the first and last column with regards to the longitudinal axis may have a single neighboring column, whereas all other columns have two neighbors. As the volume fraction of bridging elements may depend on the type of section, the longest distance along the longitudinal axis to a neighboring column may also depend on (or be indicative of) the type of section. The term “longest distance” may herein especially refer to the longer of the two distances of a column to its two neighboring columns along the longitudinal axis. With regards to a column that only has a single neighboring column, the term “longest distance” refers to the distance to that neighboring column. Each distance may especially be the shortest distance between the column and the neighboring column.

The column in the bending section may have a first longest column distance C₁, whereas a column in the basic section may have a second longest column distance C₂, wherein C₁≥2*C₂, especially C₁≥3*C₂, such as C₁≥5*C₂.

The columns, especially the columns in the bending section, may have a circular equivalent diameter dₑ, wherein the columns in the bending section have the first longest column distance C₁≤2*dₑ, especially C₁≤1.5*dₑ. In particular, C₁ may be selected from the range of 0.5*dₑ to 2*dₑ, especially from the range of 0.75*dₑ to 1.5*dₑ.

According to a second aspect of the present invention, a method for producing a bent vapor chamber element is provided. The method may comprise, providing a vapor chamber along the longitudinal axis, bending the vapor chamber along the bending section, filling the bent vapor chamber with a coolant, and sealing the bent vapor chamber.

The method may comprise closing the (bent) vapor chamber, especially by welding. In particular, the method may comprise closing of the vapor chamber after bending of the vapor chamber element.

The closing of the vapor chamber may especially leave a single opening for filling the VC with a liquid, especially a coolant.

Hence, the method may further comprise filling the (bent) vapor chamber with a liquid, especially a coolant. In particular, the method may comprise filling the vapor chamber after bending of the vapor chamber, and especially after the closing of the vapor chamber (by welding).

After filling the vapor chamber, the vapor chamber may be sealed. Hence, the method may comprise the sealing of the vapor chamber element.

In a further aspect, the invention provides a bent vapor chamber element obtainable with the method of the invention.

In embodiments, the bending section may be bent at a bending radius, r_{b}, especially wherein the bending radius, r_{b}≤3 mm, such as ≤2 mm, especially ≤1.5 mm.

The method may further comprise bending along the bending section that is to provide the bent vapor chamber having meandering shapes.

Meandering shapes may offer enhanced surface area in a compact form that may offer superior heat dissipation properties by means of convection, which may be preferred if the bent vapor chamber is to be used for cooling.

In a further aspect, the invention provides a device comprising the bent vapor chamber element of the invention. The device may further comprise an electronic component that is thermally coupled to the bent vapor chamber.

The electronic component may especially be thermally coupled, especially directly physically coupled (i.e. in physical contact), to the bent vapor chamber element. In particular, the vapor chamber element may be arranged in thermal coupling with the electronic component in order to cool the electronic component, i.e., the vapor chamber element may be configured in a heat exchanging relationship with the electronic component.

Especially, the term “thermal contact” indicates that an element can exchange energy through the process of heat with another element. The thermal contact may be achieved between two elements when the two elements are arranged relative to each other at a distance of equal to or less than about 10 μm, though larger distances, such as up to 100 μm may be possible. The shorter the distance, the better the thermal contact. Especially, the distance is 10 μm or less, such as 5 μm or less. The distance may be the separation between two respective surfaces of the respective elements. The distance may be an average distance. For instance, the two elements may be in physical contact at one or more, such as a plurality of positions, but at one or more, especially a plurality of other positions, the elements are not in physical contact. For instance, this may be the case when one or both elements have a rough surface. Hence, in embodiments in average the distance between the two elements may be 10 μm or less (though larger average distances may be possible, such as up to 100 μm). In embodiments, the two surfaces of the two elements may be kept at a distance with one or more distance holders.

Herein, the term “thermal contact” may especially refer to an arrangement of elements that may provide thermal conductivity of at least about 10 W/mK, such as at least 20 W/mK, such as at least 50 W/mK. In embodiments, the term “thermal contact” may especially refer to an arrangement of elements that may provide thermal conductivity of at least about 150 W/mK, such as at least 170 W/mK, especially at least 200 W/mK. In embodiments, the term “thermal contact” may especially refer to an arrangement of elements that may provide thermal conductivity of at least about 250 W/mK, such as at least 300 W/mK, especially at least 400 W/mK.

The device may comprise a plurality of bent vapor chamber elements.

The electronic component may comprise one or more light-emitting devices.

The light-emitting device may comprise a solid-state LED light source (such as a LED or laser diode).

The term “light source” may also relate to a plurality of light sources, such as 2 to 20 (solid state) LED light sources. Hence, the term LED may also refer to a plurality of LEDs.

Therefore, the device is configured emit light and can be considered as a luminaire or part of a luminaire. The light-emitting devices comprise one or more light sources. Especially, the one or more light-emitting devices may comprise solid-state light sources. For instance, the one or more light-emitting devices may comprise LEDs. One or more light-emitting devices are configured to generate light source light, such as in embodiments LED light. The light-emitting device is specially configured to generate device light, comprising light of one or more light sources, or especially consisting of the light of one or more light sources. The emitted light may be white light. Would the spectral power distribution of the device light be controllable, then the device light may be white light in one or more operational modes of the light-emitting device.

According a fourth aspect of the invention, a luminaire or a lighting device is provided with a device comprising one or more bent vapor chamber.

The device and/or the electronic component may comprise a driver unit comprising a driver, wherein the driver is thermally coupled with the bent vapor chamber element. For instance, the driver may be physically coupled to the vapor chamber element.

In particular, the light-emitting device may comprise an LED light generating device. For instance, the LED light-emitting device may be physically coupled to the vapor chamber element.

The device as in luminaire may be part of or may be applied in e.g. office lighting systems, household application systems, shop lighting systems, home lighting systems, accent lighting systems, spot lighting systems, theater lighting systems, fiber-optics application systems, projection systems, self-lit display systems, pixelated display systems, segmented display systems, warning sign systems, medical lighting application systems, indicator sign systems, decorative lighting systems, portable systems, automotive applications, green house lighting systems, horticulture lighting, or LCD backlighting.

The term white light herein, is known to the person skilled in the art. It especially relates to light having a correlated color temperature (CCT) between about 2000 and 20000 K, especially 2700-20000 K, for general lighting especially in the range of about 2700 K and 6500 K, and for backlighting purposes especially in the range of about 7000 K and 20000 K, and especially within about 15 SDCM (standard deviation of color matching) from the BBL (black body locus), especially within about 10 SDCM from the BBL, even more especially within about 5 SDCM from the BBL.

It is noted that the invention relates to all possible combinations of features recited in the claims. Other objectives, features, and advantages of the present inventive concept will appear from the following detailed disclosure, from the attached claims as well as from the drawings. A feature described in relation to one of the aspects may also be incorporated in the other aspect, and the advantage of the feature is applicable to all aspects in which it is incorporated.

### BRIEF DESCRIPTION OF THE DRAWINGS

The above, as well as additional objects, features, and advantages of the disclosed devices, methods, and systems, will be better understood through the following illustrative and non-limiting detailed description of embodiments of devices, methods, and systems, with reference to the appended drawings, in which:

FIG. 1 shows a perspective cross-sectional view of a vapor chamber:

FIGS. 2(a) and (b) schematically depict cross-sectional views of a bent vapor chamber and a bent section of the bent vapor chamber as shown in FIG. 2(a), respectively:

FIGS. 3(a) to (d) schematically depict a vapor chamber with varying width in the longitudinal axis, a front view of a bent vapor chamber, a cross-section view of the bent vapor chamber, and a side view of the bent vapor chamber, respectively:

FIG. 4 schematically depicts an alternative vapor chamber with varying width in the longitudinal axis, similar to FIG. 3(a):

FIGS. 5(a) to (d) schematically depict an alternative vapor chamber with varying width in the longitudinal axis, a front view of a bent vapor chamber, a cross-section view of the bent vapor chamber, and a side view of the bent vapor chamber, respectively:

FIG. 6 schematically depicts an alternative vapor chamber with varying width in the longitudinal axis, similar to FIG. 5(a):

FIGS. 7(a) and (b) schematically depict an alternative vapor chamber similar to FIG. 5(a) with an opening through the bending section and a yet another vapor chamber having a foldable stud associated with the bending section:

FIG. 8 schematically depicts a method for producing a bent vapor chamber; and

FIG. 9 schematically depicts a device having a bent vapor chamber.

As illustrated in the figures, the sizes of layers and regions are exaggerated for illustrative purposes and, thus, are provided to illustrate the general structures of embodiments of the present invention. Like reference numerals refer to like elements throughout.

### DETAILED DESCRIPTION OF THE EMBODIMENTS

The present invention will now be described more fully hereinafter with reference to the accompanying drawings, in which currently preferred embodiments of the invention are shown. This invention may, however, be embodied in many different forms and should not be construed as limited to the embodiments set forth herein: rather, these embodiments are provided for thoroughness and completeness, and fully convey the scope of the invention to the skilled person.

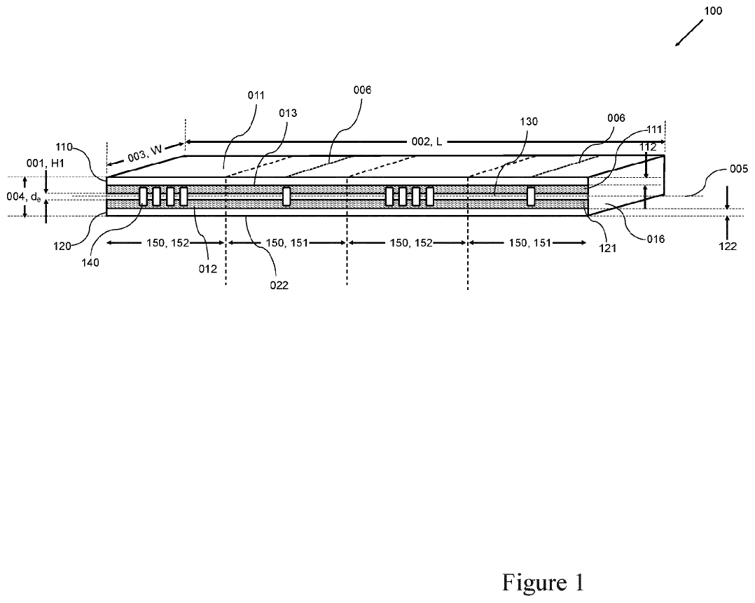

FIG. 1 schematically depicts a perspective cross-sectional view of a vapor chamber 100. The vapor chamber 100 has a length 002 (L) along a longitudinal axis 005 and a width 003 (W) defined perpendicular to the longitudinal axis 005. In this figure, the vapor chamber 100 comprises a first thermally conductive plate 110 and a second thermally conductive plate 120 with a chamber 130 in between. The height or thickness 004 (dₑ) of the vapor chamber 100 is the distance between a first outer surface 011 of the first thermally conductive plate 110 and a second outer surface 022 of the second thermally conductive plate 120. The first thermally conductive plate 110 has a first thickness 112 (d₁) and the second thermally conductive plate 120 has a second thickness 122 (d₁).

The chamber 001 comprises a wick structure. The wick structure comprises a first wick structure 111 attached to a first inner surface 013 of the first thermally conductive plate 110 facing the chamber 130. Similarly, a second wick structure 121 attached to a second inner surface 012 of the second thermally conductive plate 120 facing the chamber 130. The chamber 130 has a first height 001 (H1). The vapor chamber element 100 further comprises bridging elements 140 bridging at least part of the first height 001 (H1). The edge surfaces 016 of the vapor chamber 100 can be sealed as shown in FIG. 1.

The vapor chamber 100 further comprises a plurality of sections 150 configured along the longitudinal axis 005. In the depicted embodiment, the plurality of sections 150 comprise a bending section 151 having a first volume fraction V₁ of bridging elements 140. The plurality of sections further comprises a non-bending section 152 having a second volume fraction V₂ of bridging elements 140, especially wherein the bending section 151 is configured (directly) between two non-bending section sections 151, i.e., the bending section 151 may border two non-bending sections 152. The bending section 151 is configured to provide a bend at the middle of the bending section 006. FIG. 1 depicts that the first volume fraction V₁ of bridging elements 140 in the bending section 151 is less compared to the second volume fraction V₂ of bridging elements 140 in the non-bending section 152. The volume fraction V₁ of bridging elements 140 in the bending section 151 may be zero or none when compared to the non-bending section 152. This may allow bending with a small bending radius and easy bending of the bending section without rapturing the vapor chamber.

A ratio of the first volume fraction V₁ and the second volume fraction V₂ can be less than 1. The ratio of the first volume fraction V₁ and the second volume fraction V₂ may also be selected from a range between 0 and 0.5.

In FIG. 1, the bridging elements 140 comprise columns, especially columns having a shape selected from the group consisting of a sphere, a plate, and a cylinder, such as especially spherical columns.

The vapor chamber 100, especially the chamber 130, may comprise a wick structure 111, 121. The wick structure may especially comprise the first wick structure 111 associated with the first thermally conductive plate 110 and the second wick structure 121 associated with the second thermally conductive plate 120.

The bridging elements 140 may be at least partly comprised by the first and the second wick structures 111, 121.

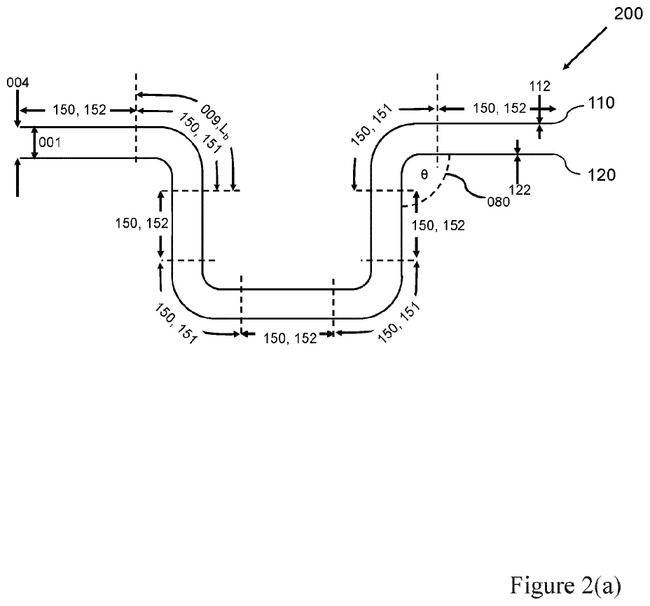

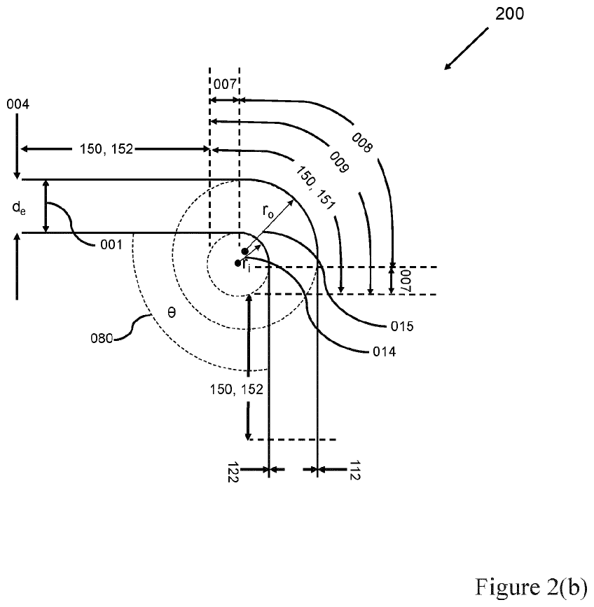

The vapor chamber 100 shown in FIG. 1 comprises bending sections 151 that can be configured to provide bent vapor chamber 200 as shown in FIG. 2. Therefore, FIG. 1 depicts the vapor chamber element 100 before bending. FIG. 2 schematically depicts the vapor chamber element 100 after bending at the bending sections 151. FIG. 2(a) schematically depicts a cross-sectional view of a bent vapor chamber 200. The vapor chamber 100 as shown in FIG. 1 may comprise a plurality of bending sections 151, especially an n bending sections 151, especially wherein n is selected from the range of 2 to 10, such as from the range of 2 to 4. In FIG. 2(a), n=4. Similarly, the vapor chamber 100 may have an (n−1) or (n+1) non-bending sections 152. In FIG. 2(a), the bent vapor chamber 200 comprises (n+1)=5 non-bending sections 152. The bent vapor chamber 200 has a constant thickness 004. However, the width (W) may vary along the longitudinal axis 005 of the vapor chamber 100. The vapor chamber 100 is bent at a bending angle 080 (θ) which is approximately 90 degrees. The bending section has a bending length 009 (Lₛ).

The first thermally conductive plate 110 and the second thermally conductive plate 120 may have (respectively) a first thickness 112 (d₁) and a second thickness 122 (d₂) independently selected from the range of 50-5000 μm.

FIG. 2(b) shows one of the bent sections of the bent vapor chamber 200 as shown in FIG. 2(a). The bending section 151 has a bending radius r_{b}, especially an inner bending radius 014 (rᵢ), or especially an outer bending radius 015 (rₒ). The bending radius, r_{b} can be the inner bending radius 014 (rᵢ), or the outer bending radius 015 (rₒ), or an average of the inner bending radius 014 (rᵢ), and the outer bending radius 015 (rₒ). The bending radius, r_{b} can be less than or equal to 3 mm. The inner bending radius 014 (rᵢ) is smaller than the outer bending radius 015 (rₒ) and the difference between the inner bending radius 014 (rᵢ), and the outer bending radius 015 (rₒ) depending on the thickness 004 (dₛ) of the vapor chamber 100.

In FIG. 2(b), the bent vapor chamber 200 has a thickness 004 (dₛ). The element thickness 004 (dₛ) is essentially the sum of the first height 001 (H1), the first thickness 112 (d₁) and the second thickness 122 (d₂). The bending section 151 has a bending length 009 (L_{b}). In particular, the bending section 151 comprises a bending subsection 151 having a bending subsection length 008 (L_{bs}) and two support subsections length 007 (Lₛₛ). Therefore, bending length 009 (L_{b})=the bending subsection length 008 (L_{bs})+2*the support subsections length 007 (Lₛₛ). The bending subsection length 008 (L_{bs}) may especially be π*(r_{b}+dₑ)/(360/θ). The support subsection length 007 (Lₛₛ) can be 3*dₑ to 20*dₑ, such as from the range of 5*dₑ to 10*dₑ. Hence, the bending length 009 (L_{b}) may especially be at least π*(r_{b}+d)/(360/θ)+2*3*dₑ, such as π*(r_{b}+dₑ)/(360/θ)+2*5*dₑ. Alternatively, the bending length 009 (L_{b}) may especially be selected from the range of π*(r_{b}+dₑ)/(360/θ)+2*3*dₑ to π*(r_{b}+dₑ)/(360/θ)+2*20*dₑ, or especially from the range of π*(r_{b}+dₑ)/(360/θ)+2*5*dₑ to π*(r_{b}+dₑ)/(360/θ)+2*10*dₑ.

The bending section 151 may have a bending length 009 (L_{b}) along the longitudinal axis 005, especially wherein the bending length 009, L_{b}≥ 0.5 mm.

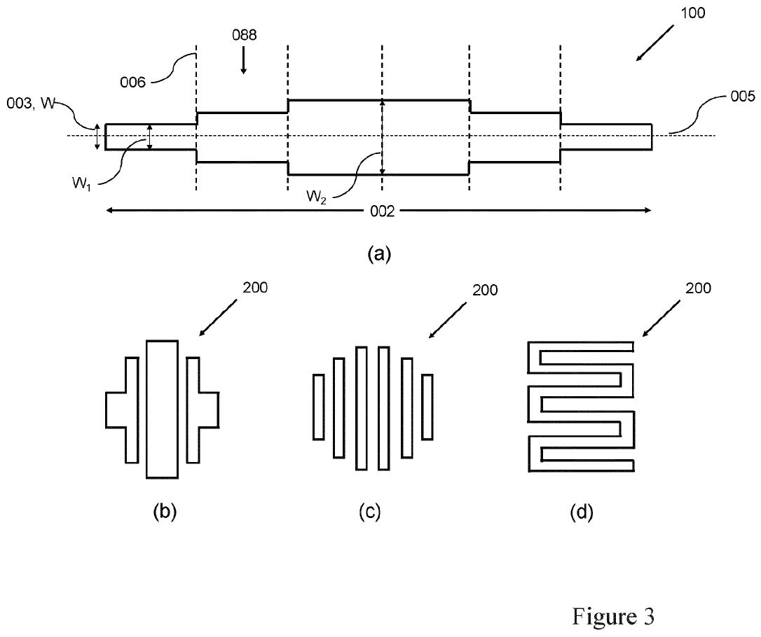

In FIG. 3(a) the vapor chamber 100 is depicted in a top view of the device and in an unbent condition. The vapor chamber 100 has bending sections with the middle of the bending sections 006 indicated in the figure. The vapor chamber 100 has rectangular cells 088 in between the middle of the bending sections 006. The width 003 (W) varies along the longitudinal axis 005 from a first width value W₁ to a second width value W₂. The relation between the width 003 (W) along the longitudinal axis 005 can be defined by a step function. Such a vapor chamber 100 can be configured in to a bent vapor chamber 200 with meandering shapes. FIG. 3(b) to (d) schematically depict a bent vapor chamber 200 obtained from folding or bending the vapor chamber 100 in FIG. 3(a) in a front view, a cross-section view; and a side view, respectively.

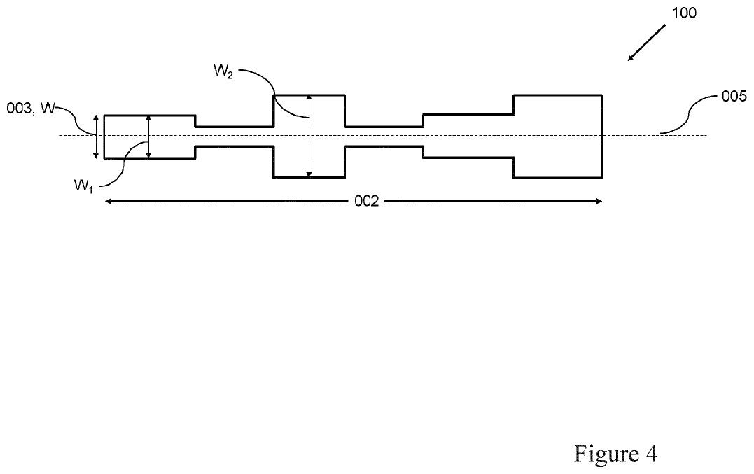

FIG. 4 schematically depicts a vapor chamber 100 with varying width 003 (W) in the longitudinal axis 005, similar to FIG. 3(a). However, the width 003 (W) varies from the first width value W₁ to the second width value W₂ in discrete step values that are random, while in FIG. 3(a) the first width value W₁ varies to the second width value W₂ gradually towards the middle and then decreases towards the end.

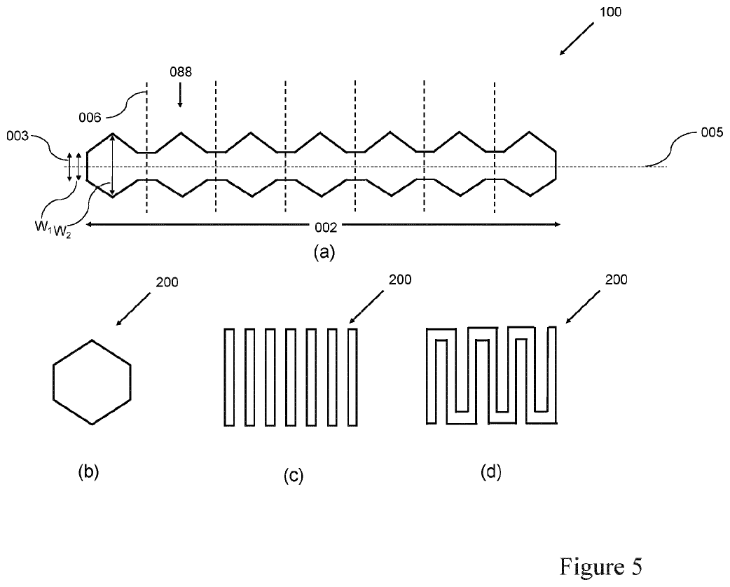

In FIG. 5(a), the vapor chamber 100 has hexagonal cells 088 in between the middle of the bending sections 006. The width 003 (W) varies from the first width value W₁ to the second width value W₂ linearly within each cell 088. Each cell 088 is adjoined by neighboring cells 088 by straight sections. FIG. 5(b) to (d) schematically depict an alternative vapor chamber with varying width in the longitudinal axis, a front view of the vapor chamber, a cross-section view of the vapor chamber, and a side view of the vapor chamber, respectively. Such a vapor chamber 100 can be configured into a bent vapor chamber 200 with meandering shapes. FIG. 5(b) to (d) schematically depict a bent vapor chamber 200 obtained from folding or bending the vapor chamber 100 in FIG. 5(a) in a front view, a cross-section view, and a side view, respectively.

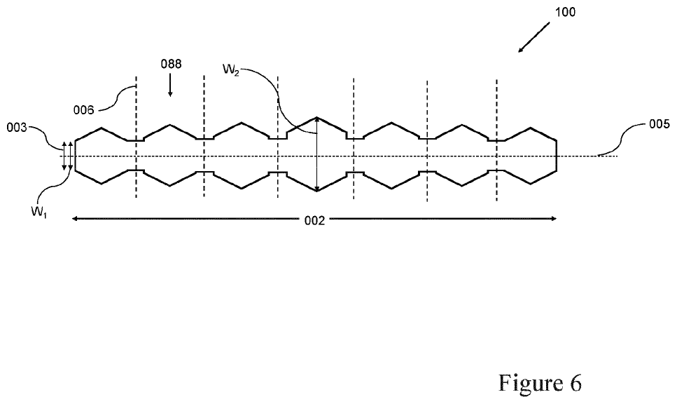

FIG. 6 schematically depicts an alternative vapor chamber 100 with varying width 003 (W) in the longitudinal axis 005, similar to FIG. 5(a). In this case, the hexagonal cell 088 sizes gradually increase towards the middle of the vapor chamber 100.

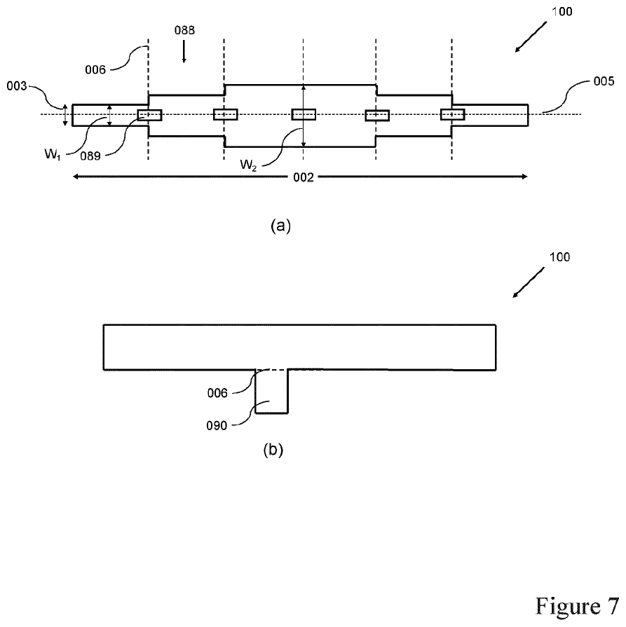

FIGS. 7(a) schematically depicts an alternative vapor chamber 100 similar to FIG. 5(a), except with openings 089 located in the middle of the bending sections 006. For folding or bending an unbent vapor chamber, an opening in the bending section with less or no bridging element compared to a non-bending section may allow easier bending with a small bending radius.

In FIG. 7(b), a vapor chamber 100 is depicted to have a foldable stud 090 associated with the middle of the bending section 006. Such a foldable stud 090 may allow easy mechanical fixation of a vapor chamber 100 with a device.

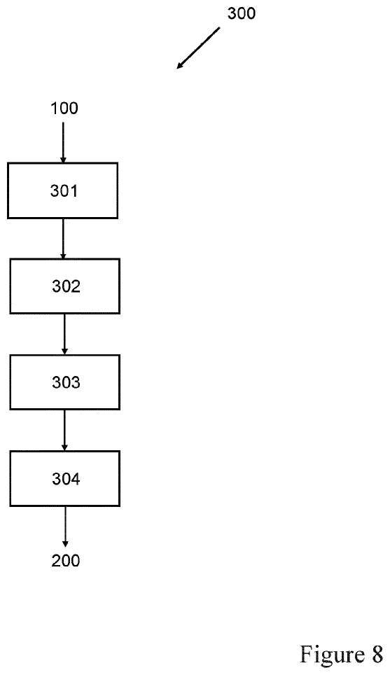

FIG. 8 schematically depicts a method 300 for producing a bent vapor chamber 200 from a vapor chamber 100 that is flat across a longitudinal axis 005 as shown in previous figures. The method 300 may start with providing 301 a vapor chamber 100 along the longitudinal axis 005. Then, bending 302 the vapor chamber 100 along the bending section 151 or in the middle of the bending section 006. Subsequently, filling 303 the bent vapor chamber 200 with a coolant in the form of a liquid or gas. Finally, sealing 304 the bent vapor chamber 200.

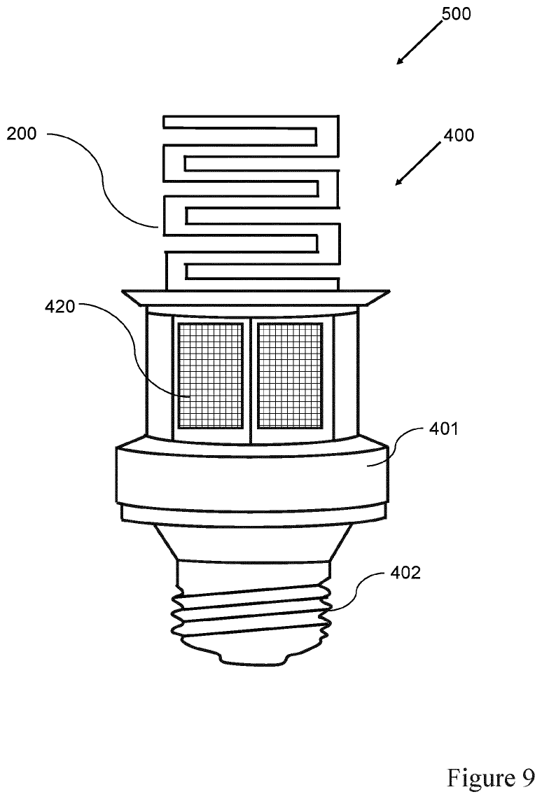

FIG. 9 schematically depicts a device 400 having a bent vapor chamber 200 obtainable with the method 300 described above. The device 200 further comprises an electronic component 410 that comprises one or more light-emitting devices 420 and the electronic component 410 is thermally coupled to the bent vapor chamber 200. The one or more light-emitting devices 420 may comprise one or more solid-state light sources (such as a LED or laser diode). The electronic component or the device may further comprise one or more driver unit and therefore, the device may comprise one or more bent vapor chambers for providing cooling of the driver unit. The device 400 is part of a lighting device 500 that further comprises a housing 401 and a fitting 402 for providing mechanical and electrical connection with a complementary socket. Therefore, the lighting device 500 can form a luminaire. The bent vapor chamber 200 is arranged to provide cooling for the electronic component 410 in such a scenario.

The term “plurality.” refers to two or more. Furthermore, the terms “a plurality of” and “a number of” may be used interchangeably.

The terms “substantially” or “essentially” herein, and similar terms will be understood by the person skilled in the art. The terms “substantially” or “essentially” may also include embodiments with “entirely”, “completely”, “all”, etc. Hence, in embodiments, the adjective substantially or essentially may also be removed. Where applicable, the term “substantially” or the term “essentially” may also relate to 90% or higher, such as 95% or higher, especially 99% or higher, even more especially 99.5% or higher, including 100%. Moreover, the terms “about” and “approximately” may also relate to 90% or higher, such as 95% or higher, especially 99% or higher, even more especially 99.5% or higher, including 100%. For numerical values it is to be understood that the terms “substantially”, “essentially”, “about”, and “approximately” may also relate to the range of 90%-110%, such as 95%-105%, especially 99%-101% of the values(s) it refers to.

The term “comprise” also includes embodiments wherein the term “comprises” means “consists of”.

The term “and/or” especially relates to one or more of the items mentioned before and after “and/or”. For instance, a phrase “item 1 and/or item 2” and similar phrases may relate to one or more of item 1 and item 2. The term “comprising” may in an embodiment refer to “consisting of” but may in another embodiment also refer to “containing at least the defined species and optionally one or more other species”.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

The devices, apparatus, or systems may herein amongst others be described during operation. As will be clear to the person skilled in the art, the invention is not limited to methods of operation, or devices, apparatus, or systems in operation.

The term “further embodiment” and similar terms may refer to an embodiment comprising the features of the previously discussed embodiment, but may also refer to an alternative embodiment.

It should be noted that the above-mentioned embodiments illustrate rather than limit the invention, and that those skilled in the art will be able to design many alternative embodiments without departing from the scope of the appended claims.

In the claims, any reference signs placed between parentheses shall not be construed as limiting the claim.

Use of the verb “to comprise” and its conjugations does not exclude the presence of elements or steps other than those stated in a claim. Unless the context clearly requires otherwise, throughout the description and the claims, the words “comprise”, “comprising”, “include”, “including”, “contain”, “containing” and the like are to be construed in an inclusive sense as opposed to an exclusive or exhaustive sense: that is to say, in the sense of “including, but not limited to”.

The article “a” or “an” preceding an element does not exclude the presence of a plurality of such elements.

The invention may be implemented by means of hardware comprising several distinct elements, and by means of a suitably programmed computer. In a device claim, or an apparatus claim, or a system claim, enumerating several means, several of these means may be embodied by one and the same item of hardware. The mere fact that certain measures are recited in mutually different dependent claims does not indicate that a combination of these measures cannot be used to advantage.

The invention also provides a control system that may control the device, apparatus, or system, or that may execute the herein described method or process. Yet further, the invention also provides a computer program product, when running on a computer which is functionally coupled to or comprised by the device, apparatus, or system, controls one or more controllable elements of such device, apparatus, or system.

The invention further applies to a device, apparatus, or system comprising one or more of the characterizing features described in the description and/or shown in the attached drawings. The invention further pertains to a method or process comprising one or more of the characterizing features described in the description and/or shown in the attached drawings. Moreover, if a method or an embodiment of the method is described being executed in a device, apparatus, or system, it will be understood that the device, apparatus, or system is suitable for or configured for (executing) the method or the embodiment of the method respectively.

The various aspects discussed in this patent can be combined in order to provide additional advantages. Further, the person skilled in the art will understand that embodiments can be combined, and that also more than two embodiments can be combined. Furthermore, some of the features can form the basis for one or more divisional applications.

1. A vapor chamber comprising:
a first thermally conductive plate and a second thermally conductive plate separated from each other by a plurality of bridging elements to form a chamber having a first height, H1,
wherein the vapor chamber having a length L along a longitudinal axis and a width W defined perpendicular to the longitudinal axis and comprises a bending section configured to provide a bend around an axis in a direction parallel with the width W, said vapor chamber further having a first volume fraction of bridging elements, and a non-bending section having a second volume fraction of bridging elements, and
wherein a ratio of the first volume fraction and the second volume fraction is less than 0.7.

2. The vapor chamber according to claim 1, wherein the ratio of the first volume fraction and the second volume fraction is selected from a range between 0 and 0.3.

3. The vapor chamber according to claim 1, wherein a ratio of the length, L and the width, W is selected from a range between 0.2 and 5.

4. The vapor chamber according to claim 1, wherein the width, W varies along the longitudinal axis from a first width value to a second width value, and wherein the second width value is selected from a range between 0.1 times of the first width value to 5 times of the first width value.

5. The vapor chamber according to claim 4, wherein the width, W varies along the longitudinal axis from a first width value to a second width value and a relation between the width, W along the longitudinal axis is defined by a linear function or a step function.

6. The vapor chamber according to claim 1, wherein the vapor chamber comprises an ‘n’ number of the bending sections, and an ‘(n−1)’, n or ‘(n+1)’ number of the non-bending sections, wherein ‘n’ is selected from a range between 2 to 20, and wherein the non-bending sections and the bending sections are arranged alternately.

7. The vapor chamber according to claim 1, wherein the vapor chamber has a thickness, dₑ, wherein the bending section is configured to provide a bend having a bending angle, θ, a bending radius, r_{b}, and a bending length, L_{b} along the longitudinal axis, and wherein the bending length, L_{b} is greater than or equal to π*(r_{b}+dₑ)/(360/θ).

8. The vapor chamber according to claim 7, wherein the bending radius, r_{b} that is less than or equal to 3 mm.

9. The vapor chamber according to claim 1, wherein the bending angle, θ is selected from a range between 45 degrees and 135 degrees.

10. The vapor chamber according to claim 1, wherein the chamber comprises a wick structure, wherein the wick structure comprises a first wick structure attached to an inner surface of the first thermally conductive plate facing the chamber and a second wick structure attached to an inner surface of the second thermally conductive plate facing the chamber.

11. The vapor chamber according to claim 1, wherein the plurality of bridging elements comprise columns.

12. A method for providing a bent vapor chamber, the method comprising:
providing a vapor chamber along the longitudinal axis according to claim 1;
filling the bent vapor chamber with a coolant; and
sealing the bent vapor chamber.

13. The method according to claim 12, wherein the method comprises bending along the bending section is to provide the bent vapor chamber having meandering shapes.

14. A device comprising the bent vapor chamber obtained with the method according to claim 12, wherein the device further comprises an electronic component thermally coupled to the bent vapor chamber.

15. The device according to claim 14, wherein the electronic component comprises one or more light-emitting devices.
